(19) United States
(12) Patent Application Publication
(10) Pub. No.: US 2015/0215111 A1
(43) Pub. Date: Jul. 30, 2015

(54) LOW JITTER DEVICE AND SYSTEM

(71) Applicant: Avago Technologies General IP (Singapore) Pte. Ltd., Singapore (SG)

(72) Inventors: Richard Ruby, Menlo Park, CA (US); Andrew Seidel, LaPorte, CO (US); Sanjeev Gupta, Santa Rosa, CA (US)

(21) Appl. No.: 14/606,981

(22) Filed: Jan. 27, 2015

Related U.S. Application Data
(60) Provisional application No. 61/932,722, filed on Jan. 28, 2014.
(60) Provisional application No. 61/932,730, filed on Jan. 28, 2014.

(51) Int. Cl. H04L 7/00; H04L 7/04; H03L 7/099

(52) U.S. Cl. CPC H04L 7/0091; H03L 7/099; H04L 7/04; H04L 7/0075

(57) ABSTRACT

A communication apparatus includes a serializer transmission circuit (TX) configured to receive a plurality of data channels in parallel, and the serializer transmission circuit (TX) transmits data serially as a data stream signal. A film bulk acoustic resonator (FBAR) is coupled with the serializer transmission circuit (TX). The film bulk acoustic resonator is part of an ultra-low phase noise reference oscillator configured to generate an ultra-high frequency reference clock signal.

### CROSS-REFERENCE TO RELATED APPLICATIONS

The present application claims priority under 35 U.S.C. §19(e) from U.S. Provisional Application No. 61/932,722 entitled “LOW JITTER DEVICE AND SYSTEM”, filed on Jan. 28, 2014. The disclosure of this provisional application is hereby specifically incorporated herein by reference. The present application claims priority under 35 U.S.C. §119(e) from U.S. Provisional Application No. 61/932,730 entitled “MEASURED RANDOM JITTER IN A 300 GBIT OPTICAL DATA LINK USING A CHIP-SCALE FBAR OSCILLATOR FOR THE REFERENCE CLOCK”, filed on Jan. 28, 2014. The disclosure of this provisional application is hereby specifically incorporated herein by reference.

### BRIEF DESCRIPTION OF THE DRAWINGS

Representative embodiments are best understood from the following detailed description when read with the accompanying drawing figures. It is emphasized that the various features are not necessarily drawn to scale. In fact, the dimensions shown in the drawings may be arbitrarily increased or decreased for clarity of discussion. Wherever applicable and practical, like reference numerals refer to like elements.

FIG. 1A shows a partial block diagram of a packaged device 100 comprising a temperature compensated oscillator.

FIG. 1B shows measured phase noise plots of a film bulk acoustic wave resonator metal oxide semiconductor (FMOS) oscillator for four temperatures.

FIG. 2A illustrates a cross-sectional view of a chip scale package FMOS system.

FIG. 2B is a diagram showing the phase noise of the FMOS device as measured at its native frequency 2576 MHz (as shown in trace 251) and after using a PECL divide by 4 circuit (644 MHz), as shown in trace 252.

FIG. 2B illustrates a block diagram of the chip scale package FMOS oscillator shown in FIG. 2A.

FIG. 2C depicts a simplified schematic block diagram of a chip scale packaged FMOS device in accordance with a representative embodiment.

FIG. 3A illustrates an alternative block diagram of the chip scale package FMOS oscillator.

FIG. 3B illustrates a block diagram of a phase lock loop;

FIG. 4 illustrates a block diagram of an evaluation system;

FIGS. 5A and 5B are diagrams depicting no aggressors versus aggressor's and relative jitter of an output of a SerDes transmitter using the FMOS oscillator for reference compared to output of the SerDes transmitter using a lab clock for reference.

FIG. 6A is a diagram comparing phase noise of 25 Gbps SerDes clock signals, when driven by the FMOS oscillator as the reference clock oscillator and when driven by two other sources.

FIG. 6B is a diagram comparing jitter of 12.89 GHz carriers of a SerDes transmitter, when driven by the FMOS oscillator as the reference clock and when driven by two other sources.

FIG. 7 illustrates evaluation results showing an eye diagram;

FIG. 8 is a diagram comparing calculated jitter at the final receiver stage of a 25 Gbps link, when driven by the FMOS oscillator as the reference clock and when driven by two other sources.

FIG. 9 is a diagram comparing phase noise of the FMOS oscillator to two other sources.

FIG. 10 is a diagram comparing jitter of the FMOS oscillator to two other sources.

### DETAILED DESCRIPTION

In the following detailed description, for purposes of explanation and not limitation, representative embodiments disclosing specific details are set forth in order to provide a thorough understanding of the present teachings. However, it will be apparent to one having ordinary skill in me art having had the benefit of the present disclosure that other embodiments according to the present teachings that depart from the specific details disclosed herein remain within the scope of the appended claims. Moreover, descriptions of well-known apparati and methods may be omitted so as to not obscure the description of the example embodiments. Such methods and apparati are clearly within the scope of the present teachings.

Unless otherwise noted, when a first device is said to be connected to a second device, this encompasses cases where one or more intermediate devices may be employed to connect the two devices to each other. However, when a first device is said to be directly connected to a second device, this encompasses only cases where the two devices are connected to each other without any intermediate or intervening devices. Similarly, when a signal is said to be coupled to a device, this encompasses cases where one or more intermediate devices may be employed to couple the signal to the device. However, when a signal is said to be directly coupled to a device, this encompasses only cases where the signal is directly coupled to the device without any intermediate or intervening devices. As used herein, “approximately” means within 10%. As used herein, when a first structure, material, or layer is to cover a second structure, material, or layer, this includes cases where the first structure, material, or layer substantially or completely encases or surrounds the second structure, material or layer.

It is to be understood that the terminology used herein is for purposes of describing particular embodiments only, and is not intended to be limiting. Any defined terms are in addition to the technical and scientific meanings of the defined terms as commonly understood and accepted in the technical field of the present teachings.

As used in the specification and appended claims, the terms ‘a’, ‘an’ and ‘the’ include both singular and plural referents, unless the context clearly dictates otherwise. Thus, for example, ‘a device’ includes one device and plural devices.

As used in the specification and appended claims, and in addition to their ordinary meanings, the terms ‘substantial’ or ‘substantially’ mean to with acceptable limits or degree. For example, ‘substantially cancelled’ means that one skilled in the art would consider the cancellation to be acceptable.

As used in the specification and the appended claims and in addition to its ordinary meaning, the term ‘approximately’ means to within an acceptable limit or amount to one having ordinary skill in the art. For example, ‘approximately the same’ means that one of ordinary skill in the art would consider the items being compared to be the same.

Relative terms, such as “above,” “below,” “top,” “bottom,” “upper” and “lower” may be used to describe the various elements' relationships to one another, as illustrated in the accompanying drawings. These relative terms are intended to encompass different orientations of the device and/or elements in addition to the orientation depicted in the drawings. For example, if the device were inverted with respect to the view in the drawings, an element described as “above” another element, for example, would now be “below” that element. Similarly, if the device were rotated by 90° with respect to the view in the drawings, an element described “above” or “below” another element would now be “adjacent” to the other element; where “adjacent” means either abutting the other element, or having one or more layers, materials, structures, etc., between the elements.

Specific embodiments of electronic devices, and methods of making such devices, will now be described below in the specific context of devices (e.g., oscillators) employing acoustic resonators, where the disclosed packaging arrangements and methods of manufacture have particular benefits. In some embodiments, first and second oscillators may each include a bulk acoustic wave (BAW) resonator, which, may be a film bulk acoustic resonator (FBAR), a solidly mounted resonator (SMR), and variations thereof such as a zero drift resonator (ZDR). It is noted, however, that the packaging of various electronic components and methods of manufacture described below have applicability and benefits for a wide variety of electronic devices other than the representative embodiments described below.

When connected in a selected topology, a plurality of the BAW resonators can act as an electrical filter. For example, the acoustic resonators may be arranged in a ladder-filter or lattice-filter arrangement, such as described in U.S. Pat. No. 5,910,756 to Ella, and U.S. Pat. No. 6,262,637 to Bradley, et al., the disclosures of which are specifically incorporated herein by reference. The electrical filters may be used in a number of applications, such as in duplexers, diplexers, triplexers, quadplexers, quintplexers, etc.

A variety of materials and methods of fabrication are contemplated for the BAW resonators of the apparatuses of the present teachings. Various details of such devices and corresponding methods of fabrication may be found, for example, in one or more of the following U.S. patent publications; U.S. Pat. No. 6,107,721, to Lakin; U.S. Pat. Nos. 5,587,620, 5,873,153, 6,507,983, 7,388,454, 7,629,865, 7,714,684 to Ruby et al.; U.S. Pat. Nos. 7,791,434 8,188,810, and 8,230,562 to Fazzio, et al.; U.S. Pat. No. 7,280,007 to Feng et al; U.S. Pat. No. 8,248,185 to Choy, et al; U.S. Pat. No. 7,345,410 to Grannen, et al.; U.S. Pat. No. 6,828,713 to Bradley, et al.; U.S. Pat. No. 7,561,009 to Larson, et al.; U.S. Patent Application Publication No. 20120326807 to Choy, et al.; U.S. Patent Application Publication No. 20100327994 to Choy, et al.; U.S. Patent Application Publications Nos. 20110180391 and 20120177816 to Larson III, et al.; U.S. Patent Application Publication. No. 20070205850 to Jamneala et al.; U.S. Patent Application Publication No. 20110266925 to Ruby, et al.; U.S. Patent Application Publication Nos. 20140292149 and 20140292150 to Zhou, et al.; U.S. patent application Ser. No. 14/161,564 entitled; “Method of Fabricating Rare-Earth Element Doped Piezoelectric Material with Various Amounts of Dopants and a Selected C-Axis Orientation,” filed on Jan. 22, 2014 to John L, Larson III; U.S. patent application Ser. No. 13/662,460 entitled “Bulk Acoustic Wave Resonator having Piezoelectric Layer with Multiple Dopants,” filed on Oct. 27, 2012 to Choy, et al.; U.S. patent application Ser. No. 13/906,873 entitled “Bulk Acoustic Wave Resonator having Piezoelectric Layer with Varying Amounts of Dopants” to John Choy, et al. and filed on May 31, 2013; and U.S. patent application Ser. No. 14/191,771, entitled “Bulk Acoustic Wave Resonator having Doped Piezoelectric Layer” to Feng, et al. and filed on Feb. 27, 2014. The entire disclosure of each of the patents, published patent applications and patent applications listed above are hereby specifically incorporated by reference herein. It is emphasized that the components, materials and methods of fabrication described in these patents and patent applications are representative and other methods of fabrication and materials within the purview of one of ordinary skill in the art are also contemplated.

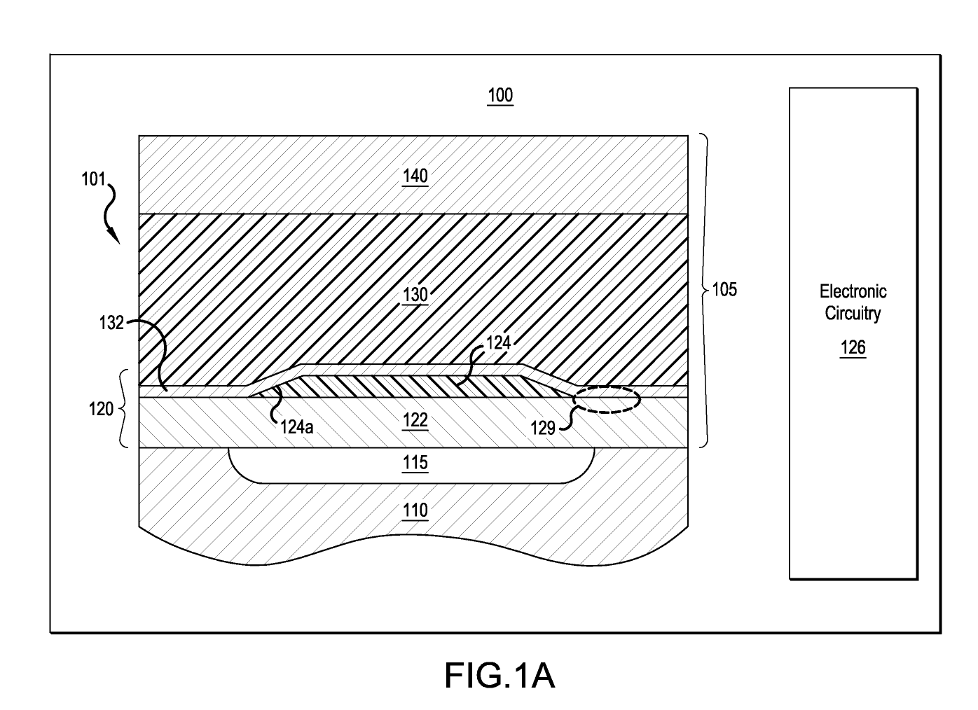

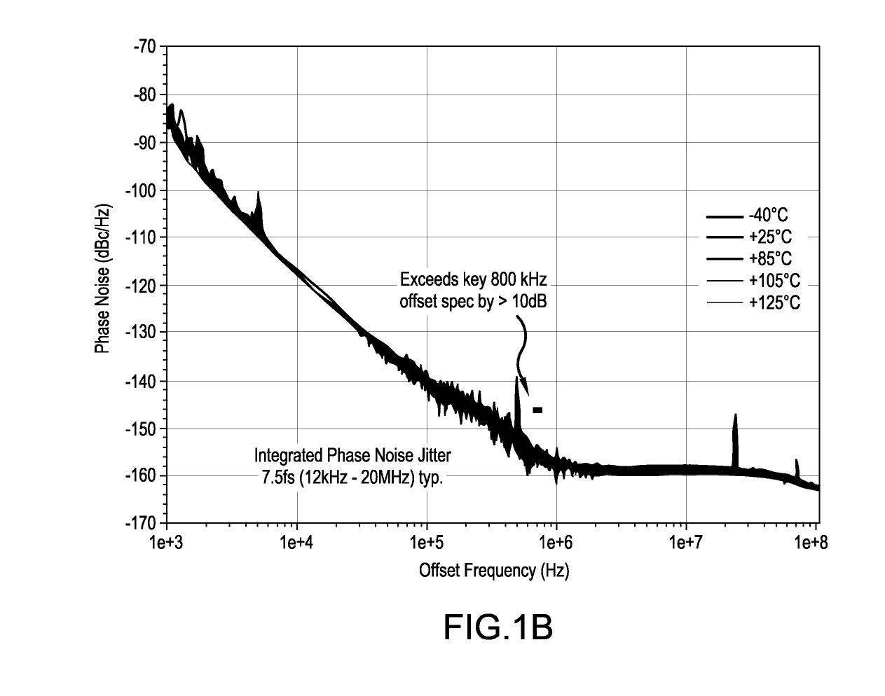

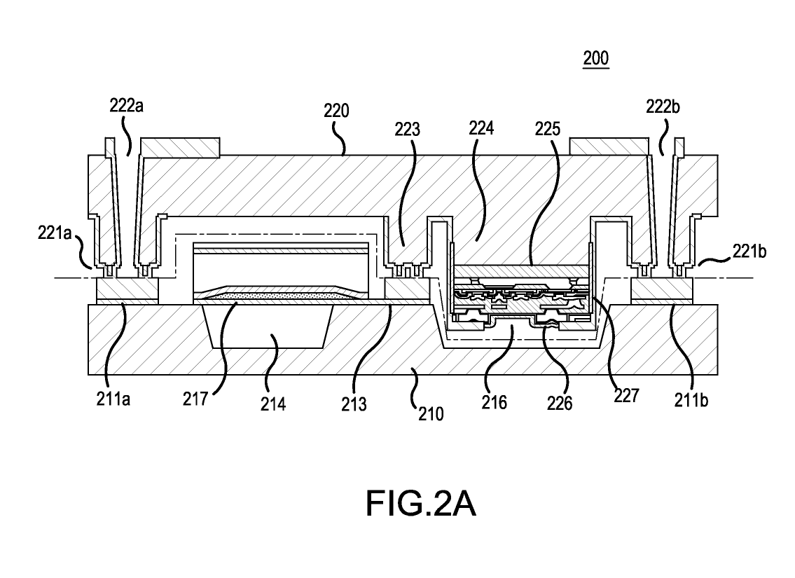

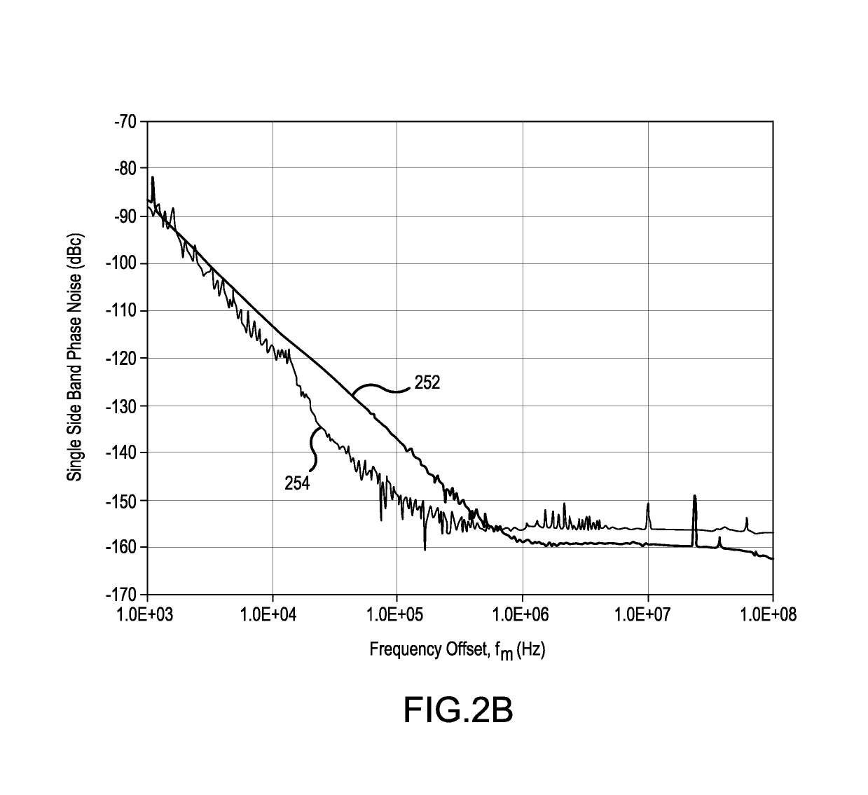

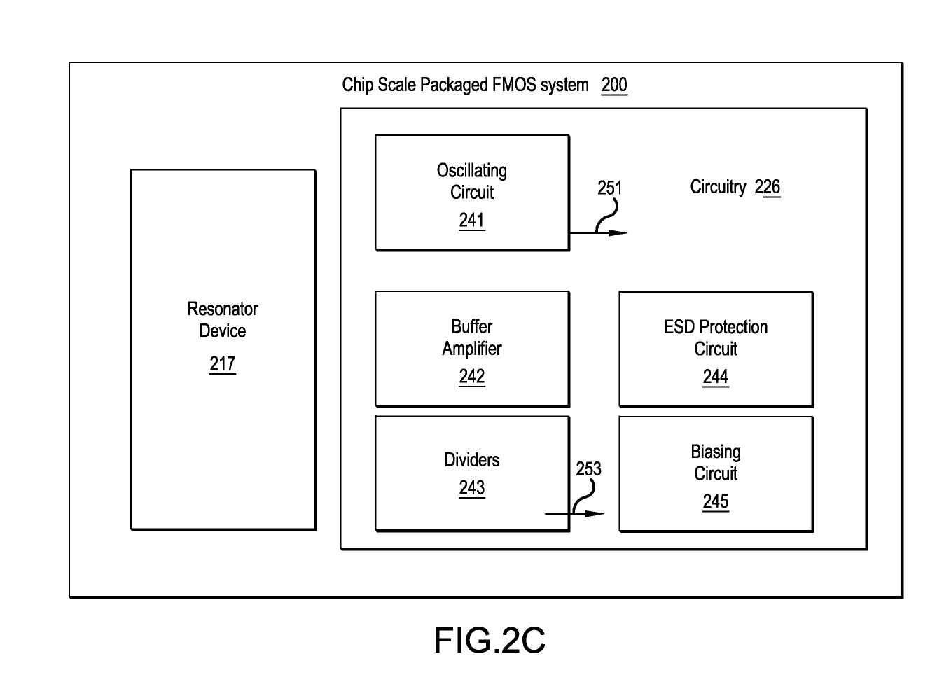

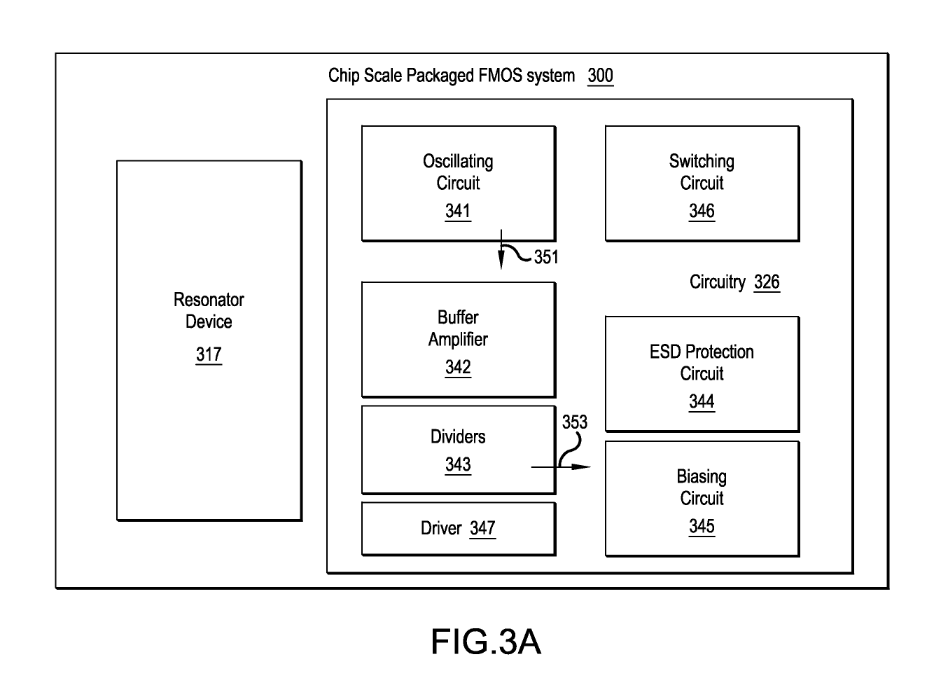

In a beneficial arrangement, a packaged device may be provided using methods and devices disclosed in commonly-owned U.S. Pat. No. 8,232,845, and U.S. patent application Ser. No. 13/162,883 filed on Jun. 17, 2011, the disclosures of which are hereby incorporated herein by references as if fully set forth herein, and aspects of which are discussed below with respect to FIGS. 1A and 2.

Device embodiments of an ultra-small oscillator working at ultra-high frequencies with sub-10 fs jitter are particularly described herein. As used herein, it should be understood that ultra-high frequency is substantially higher than the frequency of known quartz crystal resonators. As used herein, ultra-high frequency oscillators and/or ultra-high frequency clocks and/or their signals are based on the ultra-high frequency resonator, such as an FBAR, which has a resonance frequency in the range of approximately 0.5 GHz to over 10 GHz.

FIG. 1A shows a cross-sectional view of a temperature compensated BAW resonator 101, which includes an electrode having a buried temperature compensation layer 124, according to a representative embodiment. As particularly shown in FIG. 1A, a temperature compensated oscillator may comprise the temperature compensated BAW resonator 101 coupled with electronic circuitry 126. In a representative embodiment, the temperature compensated BAW resonator 101 may be a temperature compensated FBAR. Further, a packaged device may provide one or more temperature compensated BAW resonator 101 using methods and devices disclosed in above-referenced U.S. Pat. No. 8,232,845, and U.S. patent application Ser. No. 13/162,883.

Referring to FIG. 1A, illustrative temperature compensated BAW resonator 101 includes acoustic stack 105 formed on substrate 110. The substrate 310 may be formed of various types of materials compatible with semiconductor processes, such as silicon (Si), gallium arsenide (GaAs), indium, phosphide (InP), or the like, and which are useful for integrating connections and electronics. In the depicted embodiment, the substrate 110 includes a cavity 115 formed beneath the acoustic stack 105 to provide acoustic isolation, such that the acoustic stack 105 is suspended over an air space to enable mechanical movement. In alternative embodiments, the substrate 110 may be formed with no cavity 115, for example, using SMR technology. For example, the acoustic stack 105 may be formed over an acoustic mirror or a Bragg Reflector (not shown), having alternating layers of high and low acoustic impedance materials, formed in the substrate 110. An acoustic reflector such as is described in U.S. Pat. No. 7,358,831 to Larson, III, et al., is contemplated for use in an embodiment directed to an SMR-based temperature compensated BAW resonator. The disclosure of U.S. Pat. No. 7,358,831 is hereby specifically incorporated by reference herein.

The acoustic stack 105 comprises a piezoelectric layer 130 disposed between a composite first electrode 120 and a second electrode 140. In the presently described representative embodiment, the composite first electrode 120 comprises multiple layers In various embodiments, the composite first electrode 120 comprises a base electrode layer 122, a buried temperature compensation layer 124, and a conductive interposer layer 132 stacked sequentially over the substrate 110. In a representative embodiment, the base electrode layer 122 or the conductive interposer layer 132, or both, comprise electrically conductive materials, such as various metals compatible with semiconductor processes, including tungsten (W), molybdenum (Mo), aluminum (Al), platinum (Pi), ruthenium (Ru), niobium (Nb), or hafnium (Hf), for example.

Notably, the material selected for the conductive interposer layer 132 should be selected to not adversely impact the quality of the crystalline structure of the piezoelectric layer 130. Stated somewhat differently, as it is desirable to provide a highly textured (well oriented C-axis) piezoelectric layer in the acoustic stack 105, it is beneficial to use a material for the conductive interposer layer 132 that will allow growth of a highly textured (well oriented C-axis) piezoelectric layer 130. Alternatively, a seed layer (not shown in FIG. 1) can be provided beneath the conductive interposer layer 132 to foster growth of a highly textured piezoelectric layer 130.

In various embodiments, the base electrode layer 122 and the conductive interposer layer 132 are formed of different conductive materials, where the base electrode layer 122 is comprises a material having relatively lower electrical conductivity and relatively higher acoustic impedance, and the conductive interposer layer 132 is formed of a material having relatively higher electrical conductivity and relatively lower acoustic impedance. For example, the base electrode layer 122 may be formed of W, and the conductive interposer layer 132 may be formed of Mo, although other materials and/or combinations of materials may be used without departing from the scope of the present teachings. In accordance with a representative embodiment, the selection of the material for the conductive interposer layer 132 is made to foster growth of highly textured piezoelectric material that comprises piezoelectric layer 130. Further, in various embodiments, the base electrode layer 122 and the conductive interposer layer 132 may be formed of the same conductive material without departing from the scope of the present teachings.

The buried temperature compensation layer 124 is a temperature compensating layer, and is formed between the base electrode layer 122 and the conductive interposer layer 132. The buried temperature compensation layer 124 is therefore separated or isolated from the piezoelectric layer 130 by the conductive interposer layer 132, and is otherwise substantially sealed in by the connection between the conductive interposer layer 132 and the base electrode layer 122. Accordingly, the buried temperature compensation layer 124 is effectively buried within the composite first electrode 120.

The buried temperature compensation layer 124 may be formed of various materials compatible with semiconductor processes, including silicon dioxide (SiO₂), boron silicate glass (BSG), chromium oxide (Cr(x)O(Cy)) or tellurium oxide (TeO(x)), for example, which have “positive temperature coefficients.” As used herein a material having a “positive temperature coefficient” has positive temperature coefficient of elastic modulus over a certain temperature range; whereas a material having a “negative temperature coefficient,” has negative temperature coefficient of elastic modulus over the (same) certain temperature range.

The positive temperature coefficient of the buried temperature compensation layer 124 offsets negative temperature coefficients of other materials in the acoustic stack 105, including the piezoelectric layer 130. The positive temperature coefficient of the buried temperature compensation layer 124 can be selected to sufficiently offset negative temperature coefficients of other materials in the acoustic stack, so as to substantially provide a Zero Drift Resonator (“ZDR”).

As shown in the representative embodiment of FIG. 1, the buried temperature compensation layer 124 does not extend the full width of the acoustic stack 105. Thus, the conductive interposer layer 132, which is formed on the top and side surfaces of the buried temperature compensation layer 124, contacts the top surface of the base electrode layer 122, as indicated for example by reference number 129. Therefore, a DC electrical connection is formed between the conductive interposer layer 132 and the base electrode layer 122. By DC electrically connecting with the base electrode layer 122, the conductive interposer layer 132 effectively “shorts” out a capacitive component of the buried temperature compensation layer 124, thus increasing a coupling coefficient (kt²) of the temperature compensated BAW resonator 101. In addition, the conductive interposer layer 132 provides a barrier that prevents oxygen in the buried temperature compensation layer 124 from diffusing into the piezoelectric layer 130, preventing contamination of the piezoelectric layer 130.

Also, in the depicted embodiment, the buried temperature compensation layer 124 has tapered edges 124a, which enhance the DC electrical connection between the conductive interposer layer 132 and the base electrode layer 122. In addition, the tapered edges 124a enhance the mechanical connection between the conductive interposer layer 132 and the base electrode layer 122, which improves the sealing quality, e.g., for preventing oxygen in the buried temperature compensation layer 124 from diffusing into the piezoelectric layer 130. In alternative embodiments, the edges of the buried temperature compensation layer 124 are not tapered, but may be substantially perpendicular to the top and bottom surfaces of the buried temperature compensation layer 124, for example, without departing from the scope of the present teachings.

The piezoelectric layer 130 is formed on the top surface of the conductive interposer layer 132. The piezoelectric layer 130 may be formed of a thin film piezoelectric material compatible with semiconductor processes, such as aluminum nitride (AlN), zinc oxide (ZnO), lead zirconium titanate (PZT), or the like. The thickness of the piezoelectric layer 130 may range from about 9010 Å to about 901,000 Å, for example, although the thickness may vary to provide unique benefits for any particular situation or to meet application specific design requirements of various implementations, as would be apparent to one of ordinary skill in the art. In an embodiment, the piezoelectric layer 130 may be formed on a seed layer (not shown) disposed over an upper surface the composite first electrode 120. For example, the seed layer may be formed of Al to foster growth of piezoelectric layer 130 comprising AlN. The seed layer may have a thickness in the range of about 50 Å to about 5000 Å, for example.

The second electrode 140 is formed on the top surface of the piezoelectric layer 130. The second electrode 140 is formed of an electrically conductive material compatible with semiconductor processes, such as Mo, W, Al, Pi, Ru, Nb, Hf, or the like. In an embodiment, the second electrode 140 is formed of the same material as the base electrode layer 122 of the composite first electrode 120. However, in various embodiments, the second electrode 140 may be formed of the same material as only the conductive interposer layer 132; the second electrode 140, the conductive interposer layer 132 and the base electrode layer 122 may all be formed of the same material; or the second electrode 140 may be formed of a different material than both the conductive interposer layer 132 and the base electrode layer 122, without departing from the scope of the present teachings.

In a representative embodiment, an FBAR or SMR device (e.g., temperature compensated BAW resonator 101) may be used to provide a Free Running Oscillator (FRO). As described more fully below, the FBAR or SMR device may be provided in an arrangement with a semiconductor substrate (often referred to below as a lid substrate) comprising various electrical and electronic components, devices and circuits. Such an arrangement comprising an FBAR (or SMR) and such electrical and electronic components may be referred to as an FMOS device. To this end, the term “FMOS” refers generally to an arrangement in which one substrate (often referred to below as a base substrate) comprises a BAW resonator, such as an FBAR, and another substrate (the “lid substrate”) comprises the passive and active electrical devices, and circuits. In certain embodiments, the lid substrate comprises a semiconductor material (e.g., silicon) that is compatible with complimentary metal-oxide-semiconductor (CMOS) devices and well as bipolar devices, which are fabricated therein/thereover. This general arrangement of the BAW resonator (e.g., FBAR) on the base substrate aid the CMOS/bipolar devices on the lid substrate lends itself to the acronym FMOS. However, it is to be noted that the lid substrate is not limited to materials normally reserved for MOS and bipolar technologies. Rather, the lid substrate may comprise silicon-on-insulator (SOI) substrates; and III-V semiconductor materials (e.g., binary and ternary materials) comprising, for example, heterojunction bipolar transistor (HBT) circuits, or high electron mobility transistor (HEMT), or pseudomorphic HEMT (pHEMT) circuits.

In representative embodiments described herein, device (e.g., oscillators, resonators, etc.) frequencies may be approximately 2 GHz to approximately 4 GHz. In other embodiments, device frequencies may be approximately 600 Mhz to approximately 5 Ghz. The frequency accuracy over all process variation, aging, temperature range, Vdd, and load variation can be approximately +/−500 ppm up to approximately +/−2000 ppm for more relaxed requirements. Jitter may be low or more specifically ultra-low, on the order of approximately 10 femto-seconds or less. FIG. 1B shows measured phase noise plots of a 2,608 GHz FMOS Oscillator for four temperatures. The phase noise plot is measured at −40 C, 25 C, 105 C. The design specification was to meet −147 dBc/Hz at 800 KHz offset (for GSM requirements). The far-from-carrier spurs are noise picked up from the test lab and the close-in noise is from vibration from the Temptronics temperature controller.

The output signal for this device is differential and output power is typically 2 to 4 dBm for a 3.3V Vdd. Operating range of Vdd is approximately 2V to approximately 5V and the current draw at 3.3V Vdd is typically 18 mA. The 12 KHz to 20 MHz random jitter value can be 8 fs to 10 fs. The device may work comfortably up to 125° C.; above that, the ESD circuits may begin to break down. Illustratively, the transistor used for this is a bipolar transistor with an ft of 25 GHz.

In another representative embodiment, an FBAR or SMR device (e.g., temperature compensated BAW resonator 101) may be used to provide a Voltage Controlled Oscillators (VCO's) in an FMOS arrangement. For demonstration purposes, a Pierce type oscillator is used (vs. the Differential Colpitts Oscillator topology used for the FRO). The base-to-resonator node may be brought out to one of the contact pads (not shown). Here, an external varactor may be connected in shunt and may be used to pull the frequency of the free running oscillator. An integrated inductor and capacitors may be used to convert the single ended output of the Pierce topology into a differential output at the contact pads.

The FMOS VCO of a representative embodiment can provide an ultra-low phase noise reference oscillator configured to generate an ultra-high frequency reference clock signal. Table 1 lists the measured performance of three such VCOs running at 2 GHz, 2.5 GHz and 3 GHz. All FMOS VCO's measured in Table 1 were at Vdd=3.3 V. Idd typically was around 20 mA. It is noted that only the 2500 MHz FMOS VCO was optimized for tuning and power output.

TABLE 1

| | Output Power | Tuning | PN@ | PN@ | PN@ | | |
|---|---|---|---|---|---|---|---|
| Device | (over tuning) | Range | 10 Khz | 100 KHz | 1 MHz | jitter | comments |
| 1996 Mhz | −9 to 14 dBm | 1000 ppm | −117 dBc/Hz | −144 dBc/Hz | −160 dBc/Hz | 6.6 fs | integrated |
| | | | | | | | inductor |
| | | | | | | | not optimized |
| 2500 Mhz | −1 to 0 dBm | 2000 ppm | −114 dBc/Hz | −138 dBc/Hz | −158 dBc/Hz | 17 fs | Optimized |
| 2949 Mhz | 1 to 2 dBm | 400 ppm | −105 dBc/Hz | −130 dBc/Hz | −150 dBc/Hz | 35.5 fs | Not optimized |
| | | | | | | | for tuning - |
| | | | | | | | expect >1000 |
| | | | | | | | ppm |

One of the benefits that may flow from one embodiment using bipolar transistors in the lid substrate (described below) is that the close-in phase noise may be very low. The typical offset frequency where the flicker noise contribution from the oscillator circuit “kicks in” may be 100 KHz to 200 KHz for FETs. However, for bipolar transistors, the flicker noise component may start between 10 KHz and 20 KHz offset. Since the l/f component of the flicker noise may be converted into a l/f3 phase noise dependence, about 10 dB per decade better phase noise close-in may be exhibited starting from approximately 100 KHz to approximately 10 KHz for bipolar transistors. On the resonator side, the AlN piezoelectric layer of the FMOS VCO may have the unusual ability to handle large amounts of power without going non-linear. In certain representative embodiments, comparatively low-jitter oscillators with up to 90 mA of displacement current generated in the device. The ability to ‘dump’ large amounts of power into the FMOS VCO may provide a very low far-from-carrier phase noise floor.

Since jitter is the integrated phase noise of the VCO, the far-from-carrier noise floor and the lower close-in phase noise contributions from the bipolar transistor may achieve superior jitter. As described in the above sections, sub-10 femto-second jitter is exhibited in designs (where the limits of the integrated jitter are from 12 KHz to 20 MHz). Of course, there may be limitations as to what kinds of circuits that can be constructed using bipolar transistors. If digital logic is needed, then there may be design trade offs as to some of that jitter performance in exchange for more flexibility.

For example, in contrast to bipolar, devices may be implemented in CMOS technology. There may be some degradation of the jitter when replacing the bipolar transistor with a FET, but there may also be some added benefits from added digital circuitry. For example, a “wish list” of functions to add to the fundamental oscillator can be created. Among these may be the ability to “fine tune” the output frequency to compensate for process variations and inadequacy or limitation of the ion mill tools to achieve fine frequency adjustments. Beyond that, one might ask for a Low voltage Drop Out (LDO) to eliminate or mitigate frequency pulling due to variations in the supply voltage, and “bullet-proof” ESD circuits to cover usage in hostile environments. Dividers would be desired, along with a library of output drives (LVDS, PECL, CML . . . ). Even an All Digital PLL (ADPLL) may be employed to provide a variety of frequency products.

FIG. 2A shows a cross-sectional view of a chip scale packaged FMOS device 200 (hereafter FMOS device 200) in according to a representative embodiment. Referring to FIG. 2A, the FMOS device 200 comprises a base substrate 210, a lid substrate 220, first bonding pads 211a and 211b, a second bonding pad 213, a first recessed region 214, and a second recessed region 216, a BAW resonator 217, bonding pad seals 221a and 221b, a drop down contact post 223, a pedestal 224, a low-resistivity material layer region 225 and an integrated die comprising electronic circuitry 226. Notably, the bonding pad seals 221a, 221b bond with the first and second bonding pads 211a,211b and 213 to define a hermetically sealed volume between the lid substrate 220 and the base substrate 210.

In accordance with a representative embodiment, the base substrate 210 and the lid substrate 220 each comprise silicon (Si). However, as noted above, this is not essential, with the material selected for the lid substrate 220 dictated by the desired devices provided therein and thereover. Generally, although not necessarily, the base substrate 210 and the lid substrate 220 each comprise the same material. This can be useful from the standpoint of processing efficiency.

Lid substrate 220 of FMOS device 200 may comprise an electrically insulating layer 227, which electrically isolates a low-resistivity material layer (e.g., epitaxial layer) region 225 from one or more electrically conductive (e.g., metal) laws or traces in contact with bonding pad seal(s) 221 and drop down contact post(s) 223. In some embodiments, electrically insulating layer 227 partially or totally encompasses (surrounds) low-resistivity material layer (e.g., epitaxial layer) region 225. The BAW resonator 217 may comprise the temperature compensated BAW resonator 101 shown in FIG. 1 or other BAW resonators (not shown) comprising a temperature compensation layer, such as described in the above-referenced U.S. Patent Application Publication Nos. 20140292149 and 20140292150 to Zhou, et al. The BAW resonator 217 may be implemented in a single die using process suitable to build acoustic resonators. Alternatively or additionally, the circuitry may be implemented into lid substrate 220 as shown in FIG. 2A (e.g., as electronic circuitry 226 is integrated).

As depicted, the base substrate 210 comprises first recessed region 214 and second recessed region 216. The first recessed region 214 provides the cavity or “swimming pool” in embodiments the BAW resonator 217 is an FBAR. The second recessed region 216 is configured to receive the pedestal 224.

Illustratively, the pedestal 224 comprises circuitry and is a component of the lid substrate 220. The lid substrate 220 illustratively comprises thru vias 222a, 222b, which are connected to circuitry, such as the circuitry of the pedestal 224. As can be appreciated, by virtue of the comparatively compact structure of the FMOS device 200, the BAW resonator 217 may be provided in close proximity to the circuitry. In other representative embodiments, the second recessed region 216 is foregone, and the pedestal 224 is maintained over an upper surface of the base substrate 210 (e.g., by standoffs (not shown) to provide more surface area in the pedestal 224, enabling additional circuitry to be provided over the pedestal 224.

In a representative embodiment, packaging of BAW resonator 217 in the FMOS device 200 with electronic circuitry to provide a substantially fixed frequency oscillator can provide advantages of small size and performance. For purposes of illustration and not limitation, the dimensions of the FMOS device 200 may be approximately 1×1 mm² with a height of approximately 0.23 mm. This device may comprise a hermetically sealed oscillator using an FBAR as the high Q resonator. The external 1×1 mm² package may comprise six pads and may be coupled and/or integrated with an Application Specific Integrated Circuit (ASIC) using standard Surface Mount Technology (SMT) assembly techniques.

In one embodiment, FMOS device 200 comprising a 2.5 GHz differential output oscillator design provides a low mean random jitter of approximately 7.5 femtoseconds—12 KHz to 20 MHz—(sample size was >10,000). The fundamental frequency of the oscillator comprising BAW resonator 217 is approximately 2.608 GHz. A low mean phase noise at approximately 800 KHz offset is approximately −157 dBc/Hz. Typical drift over industrial temperature ranges may be less than +/−100 ppm (parts per million). The FMOS device 200 of such an embodiment may be substantially all-silicon, may be hermetically packaged, and may comprise a high frequency oscillator comprising BAW resonator 217. Such an FMOS device is contemplated for use, for example, in a high speed SERializer/DESerializer (SERDES) and/or a fiber optic communication device or system. Accordingly, in one illustrative embodiment, the FMOS device 200 provides a substantially all-silicon packaged oscillator comprising BAW resonator 217, combined with IC circuits integrated into a package, which has dimensions of approximately 1×1 mm² with a height of approximately 0.2 mm.

The foregoing device may be implemented so as to be substantially agnostic as to what ‘flavor’ of integrated circuit used. Such advantages may flow from embodiments of the device comprising two silicon die (bonded together using wafer-bonding techniques), one holding the resonator, the other holding the integrated circuit. The base wafer may contain the resonator, which may comprise a FBAR device. Dimensions of the die may be about 0.3 mm2 by 0.23 mm in height.

Resonators can be tuned to an appropriate frequency in various ways. For example, using techniques which may be similar to what may be used for tuning in quartz resonators. Frequencies may be measured and a small amount of material may be ‘ion milled’ off one of the surfaces. Ion milling may use a flux of argon ions to knock off atoms from the surface of the electrode. This may reduce the mass of the electrode and may incrementally increase the frequency of the resonator.

However, it should be understood that a packaged ZDR resonator exhibits significant differences from a quartz resonator. Ion milling works very well for quartz resonators (whose thickness might range from 0.3 to 0.5 mm thick) where only a few atomic layers are removed. But for FBAR, the total stack thickness is only one to two um. Accordingly, it should be understood that there may be some lack of precision of the final frequency. There may be limits to ‘tuning’ a resonator to a target frequency using ion milling (as described above). For example, in some cases there may be approximately +/−500 ppm to +/−1000 ppm accuracy at 1 GHz.

Features of hermeticity, high Q, small size and high volume manufacturing may be good starting points, guiding use of an FBAR for time and frequency applications. Temperature compensation as described herein may help to overcome one problem with standard FBAR, which may otherwise have a temperature coefficient of frequency (TCF) of about −30 ppm/C. The operating temperature range for filter/duplexers in a cell phone may be about −40 to 85 C (industrial temperature range). Beyond that, the filter may be required to handle another 30 C due to self heating and heat emanating from nearby power amplifiers and base hand microprocessors. In such circumstances, the resulting full range may otherwise lead to +/−2400 ppm of frequency shift.

As can be appreciated, a temperature compensated BAW resonator, such as described above, provides improved performance through a reduced frequency shift. The acoustic stack can be designed such that the linear dependence of frequency vs. temperature may be substantially negligible. That said, higher order terms may be present, most notably, the quadratic term, β, and to a lesser extent, the third order term, γ. For some embodiments of acoustic stack designs, the total frequency shift may be less than approximately +/−100 ppm over the industrial range.

In light of all of the foregoing, it should be understood that certain representative embodiments may provide: 1) a modified FBAR resonator, the ZDR; 2) a hermetically packaged part in a comparatively small form factor; 3) Q that may range from approximately 2500 to approximately 5000 and an f*Q product that may be within a factor of 10 of typical Quartz resonators; and 4) parts that may be manufacturable in comparatively high volumes.

Furthermore, since the resonator and oscillating circuit are in intimate contact and connected by solid silicon connections (or ‘drop downs’), the device is far more resistant to vibration and acceleration compared to oscillators that use discrete resonators connected using wire bonds and held by epoxy.

FIG. 2B is a diagram showing the phase noise of the FMOS device as measured at its native frequency 2576 MHz (as shown in trace 252) and after using a PECL divide by 4 circuit (644 MHz), as shown in trace 254. As can be seen, the far-from-carrier noise is degraded by 5 dB from 1 MHz offset and beyond (hence the degradation in jitter), but, closer in, the phase noise is improved by the expected 12 dB per decade (due to the div4). Below about 20 kHz, we see that the close-in phase noise is abruptly degraded. This could be noise from the dc power supply, or other noise sources. It is contemplated that the 12 dB improvement in performance of the div4 part down to at least 1 kHz or better can be realized.

FIG. 2C depicts a simplified schematic block diagram of a chip scale packaged FMOS device 200 in accordance with a representative embodiment. In accordance with an embodiment, the simplified schematic block diagram comprises an oscillator. As shown in FIG. 2A and FIG. 2C, the chip scale packaged FMOS device may comprise the BAW resonator 217 integrated in a single die (i.e., the base substrate 210), with the BAW resonator 217 disposed within the first recessed region 214, and the electronic circuitry 226 of the lid substrate 220 disposed in the second recessed region 216. The electronic circuitry 226 may comprise an oscillating circuit 241, a buffer amplifier 242, a divider 243, an ESD protection circuit 244 and a biasing circuit 245. The electronic circuitry 226 may be integrated into a single die (i.e., lid substrate 220) having the oscillating circuit 241 as well as at least one or even all of the circuit blocks, i.e. the buffer amplifier 242, the dividers 243, the ESD protection circuit 244 and the biasing circuit 245.

The oscillating circuit 241 may be electrically coupled with the BAW resonator 217 to produce an oscillating signal 251 (referred to below as a first frequency output signal 251.) The first frequency output signal 251 may be coupled to the buffer amplifier 242 so as to be output externally. Alternatively, the first frequency output signal 251 may be coupled to the dividers 243 so as to produce a second frequency output signal 253 having a lower frequency before being output externally through the buffer amplifier 242. The ESD Protection Circuit 244 may be for electrostatic discharge protection purpose whereas the biasing Circuit 245 may comprise by-pass capacitors (not shown) and other circuitry (not shown) configured to produce a biasing voltage to the oscillating circuit 241 and/or the BAW resonator 217. The BAW resonator 217 may comprise substantially filtering circuit that may be coupled to the oscillating circuit 241 to obtain a periodic signal with low jitter. In one embodiment, the jitter may be less than 10 fs. The low jitter may be attributed by the arrangement of the oscillating circuit 241 in such a manner to have BAW resonator 217 integrated into a single chip, and other circuits integrated into the electronic circuitry 226 that may be disposed in the second recessed region 216 adjacent to the first recessed region 214. Other packaging arrangements and aspects disclosed in FIG. 2A may contribute towards smaller package size, which indirectly contributed towards the low jitter performance. The electronic circuitry 226 may be implemented using a bipolar process or a CMOS process. Since jitter is the integrated phase noise of the FMOS device 200, the far-from-carrier noise floor from the BAW resonator 217 and the lower close-in phase noise contribution from the bipolar transistor in the electronic circuitry 226 may enable the system to achieve superior jitter relative to conventional oscillators implemented using a single die in a CMOS or a bipolar process.

FIG, 3A depicts a chip scale packaged FMOS device 300 in accordance with a representative embodiment. Many aspects and details of the various components described in connection with representative embodiments in FIGS. 1A-2C are common to the presently described representative embodiment, and are not repeated in order to avoid obscuring the its description.

Chip scale packaged FMOS device 300 may comprise a BAW resonator 317, a circuitry 326 having an oscillating circuit 341, a buffer or an amplifier 342, a frequency divider 343, a driver 347, a biasing circuit 345, an ESD Protection Circuit 344, and a switching circuit 346. The chip scale packaged FMOS device 300 may be substantially similar to the FMOS device 200 shown in FIG. 2A and FIG. 2B but differs at least in that the circuitry 326 of the chip scale packaged FMOS device 300 may be integrated using a CMOS process. As such, the chip scale packaged FMOS device 300 may comprise switching circuit 346, which together with the oscillating circuit 341 may be configured to generate a first frequency output signal 351. The frequency divider 343 may be configured to divide down the first frequency output signal 351 to obtain a second frequency output signal 353 having a lower frequency relative to the first frequency output signal 351.

The switching circuit 346 may comprise switch capacitor circuits or other circuits configured to compensate process variation. In another representative embodiment, the switching circuit 346 may be configured to achieve fine frequency adjustment by having some programmable switches to fine tune the frequency of the oscillating circuit. The buffer 342 may be configured to receive the first frequency output signal 351. The driver 347 may comprise output drivers such as Low voltage differential signal driver (referred as an LVDS driver) (not shown), Emitter Coupled Logic driver (referred as an ECL driver) (not shown), and a current mode logic driver (referred as a CML driver) (not shown) that may conform an engineering standard.

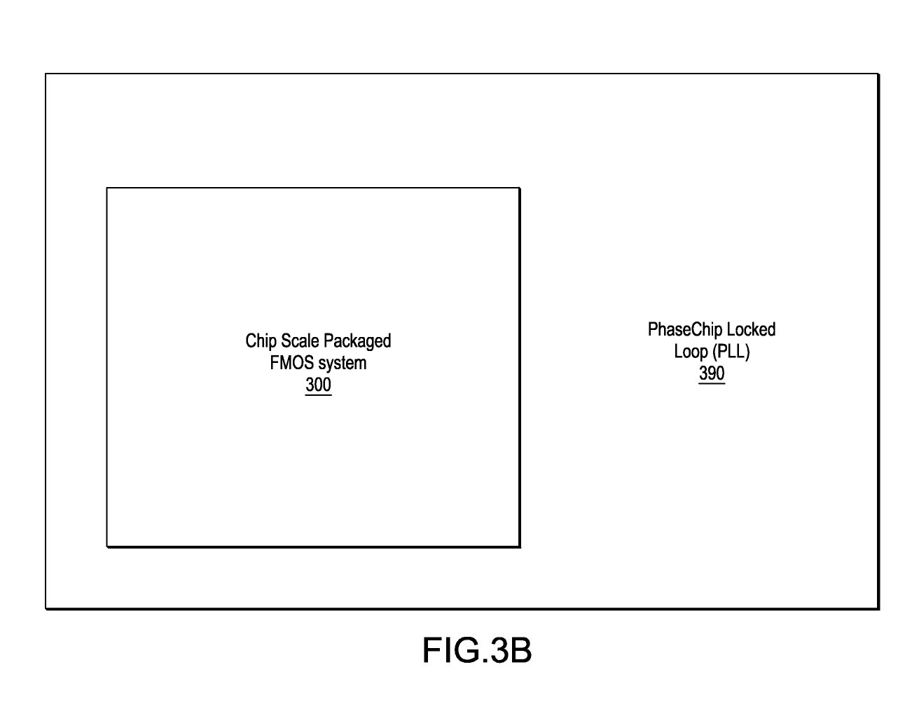

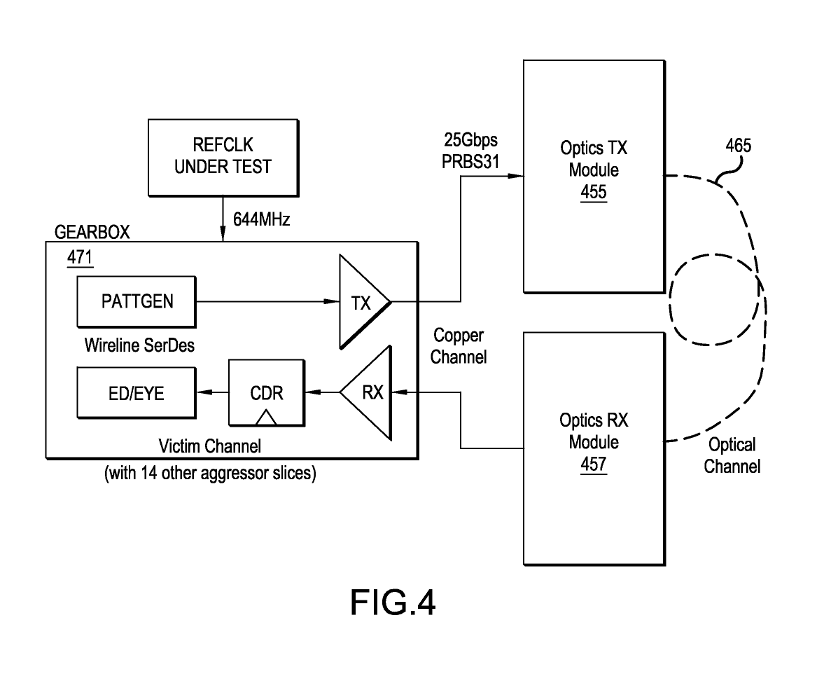

Further, the chip scale packaged FMOS device 300 may be a portion of a phase locked loop circuit (PLL) 390 (see FIG. 3B) that may be used to create a variety of frequency products. The PLL circuit 390 may be an analog PLL or a full digital PLL.

In some embodiments, phase locked loop circuit (PLL) 390 may be coupled with the ultra-low phase noise reference oscillator (not shown in FIGS. 3A-3B) and configured to generate a transmission clock signal based on an ultra-high frequency reference clock signal. For example, the phase locked loop circuit (PLL) 390 may be coupled with the ultra-low phase noise reference oscillator of the chip scale packaged FMOS device 300, and may comprise a phase detector, and may further comprise a VCO (not shown in FIGS. 3A-3B) configured to generate an output of a transmission clock signal. For example, the phase detector (not shown) of the phase locked loop circuit (PLL) 390 may have a reference clock input coupled with the ultra-low phase noise reference oscillator of the chip scale packaged FMOS device 300. The phase detector of the phase locked loop circuit (PLL) 390 may have a transmission clock input coupled with the output of the voltage controlled oscillator. More specifically, a divider (not shown) may be used to divide down the transmission clock signal, and the phase detector of the phase locked loop circuit (PLL) 390 may have a divided-down transmission clock input coupled with the output of the voltage controlled oscillator through the divider.

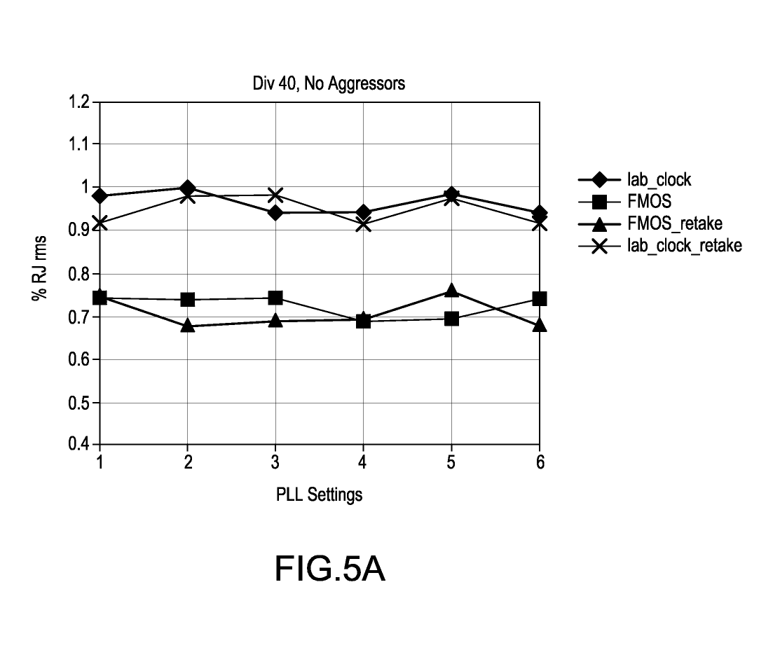

As will be discussed in greater detail subsequently herein, in a representative embodiment, chip scale packaged FMOS device 300 may be used in a communication apparatus comprising a serializer transmission circuit (TX) of a SerDes, which can be coupled with the ultra-low phase noise reference oscillator (e.g. the FMOS oscillator as reference clock) through the phase locked loop circuit (PLL). For example, as depicted in connection with optical data link system 400 in FIG. 4, a gearbox integrated circuit 471 and/or retimer PATTGEN pattern generator may incorporate the phase locked loop circuit (PLL) to generate a transmission clock signal, and a serializer transmission circuit (TX) of a SerDes of the gearbox integrated circuit 471, which may be coupled with the ultra-low phase noise reference oscillator through the phase locked loop circuit (PLL).

In other words, for the REFCLK UNDER TEST shown in FIG 4, the ultra-low phase noise reference oscillator (e.g. the FMOS oscillator as reference clock) can be coupled with the serializer transmission circuit (TX) of the SerDes through the phase locked loop circuit (PLL) via the transmission clock signal. Further, as will be discussed in greater detail subsequently, for the sake of results comparison, there can be a replacement at the REFCLK UNDER TEST shown in FIG. 4 of the ultra-low phase noise reference oscillator (e.g. the FMOS oscillator as reference clock) with a standard clock.

In FIG. 4 the serializer transmission, circuit (TX) of the SerDes may be configured to receive the transmission clock signal and a plurality of data channels in parallel and wherein the serializer transmission circuit (TX) transmits data serially as a data stream signal. The communication apparatus may further comprise a deserializer receiver circuit (RX) having a clock and data recovery circuit (CDR) coupled with serializer transmission circuit (TX) and configured to substantially recover the transmission clock signal from the data stream signal as a recovered clock signal. The communication apparatus may be configured in simplex mode or may be configured in duplex mode. In a beneficial arrangement, Optics Module, SerDes and more particularly SerDes gearbox may be provided using methods and devices disclosed in U.S. patent application Ser. No. 13/460,833 filed on Apr. 30, 2012 in the names of Faouzi Chaahoub, et al., and further disclosed in U.S. patent application Ser. No. 13/544,199 filed on Jul. 9, 2012 in the name of Faouzi Chaahoub, et al., the entirety of each of which are hereby incorporated herein by references as if fully set forth herein, and aspects of which are discussed below with respect to FIG. 4. It should be understood that while an optical channel (e.g. use of optical fiber) is shown in FIG. 4, the foregoing teachings can be independent of media. In other words, other media such as wire or wireless transmission can be used.

Beneficially, the optical link shown in FIG. 4 comprises both SerDes chips (using re-timers and CDRs) along with the electrical to optical converters.

In a representative embodiment depicted in FIG. 4, oscillators are implemented to drive the SerDes device, to generate a signal for an example application of the IEEE 802.3ba 100 Gigabit Ethernet in a by-four mode (25 G). Illustratively, an eight-channel retime, commercially available from Avago Technologies, San Jose, Calif. (USA) was used as the PATTGEN in FIG. 4. This is an ASSP designed in 28 nm, with an operating range from 1 to 28 Gbps, and used here in its standalone pattern generator mode.

Illustratively, to establish a jitter measurement of the SerDes transmitters, the retimer PATTGEN was configured to send a 0101 . . . pattern, as driven by the various reference clocks, DIV40, resulting in a 12.890625 GHz carrier or transmission clock signal. For a reasonable test, all other parallel data channels were enabled, sending pseudo-random bit sequences (PRBS), to stimulate on-die switching noise. As the other parallel data channels were not terminated to 50 Ohms as a receiver would provide in a full system, unreasonable jitter would result by driving in to open circuit, so the aggressors' final driver stages were disabled, in lieu of a large number of 2.4 mm terminators, which although beneficial, are comparatively expensive.

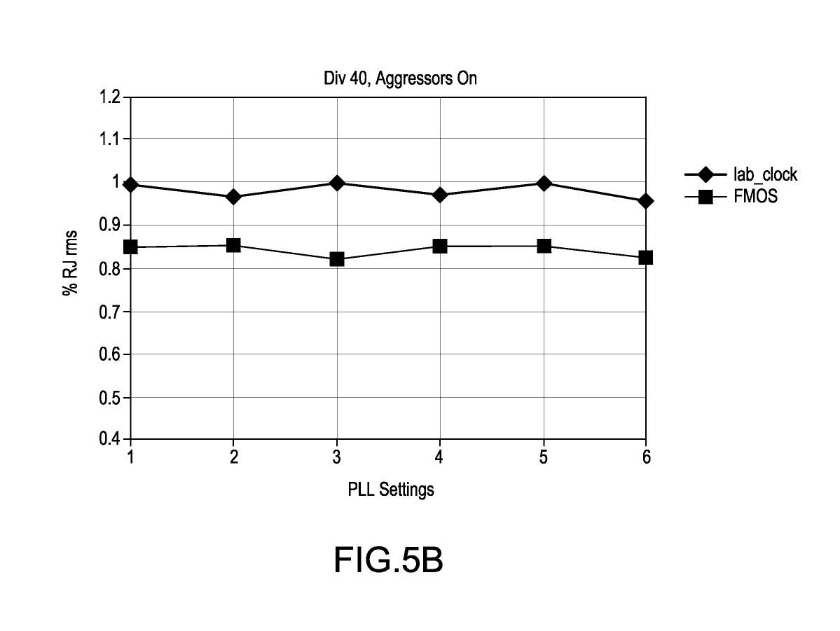

FIGS. 5A and 5B are diagrams depicting no aggressors versus aggressors and relative jitter of an output of the SerDes transmitter using the FMOS oscillator for the reference clock compared to output of the SerDes transmitter using a standard lab clock for reference.

FIGS. 5A and 5B show the relative jitter as measured at the output of a SerDes prototype circuit with and without aggressors on (parallel channels that inject noise into the primary channel). A comparison was made between the known oscillator and the FMOS oscillator reference clock of a representative embodiment. In the case of no aggressors on, the output phase noise was improved by approximately 34% (using optimum PLL settings) using the FMOS oscillator reference clock of a representative embodiment, in the case with the Aggressors turned on, the output jitter using the FMOS oscillator reference clock of a representative embodiment improved by ˜18% over a known clock. What is encouraging is that in a well-designed PLL, the phase noise advantage of the FMOS oscillator reference clock can filter through.

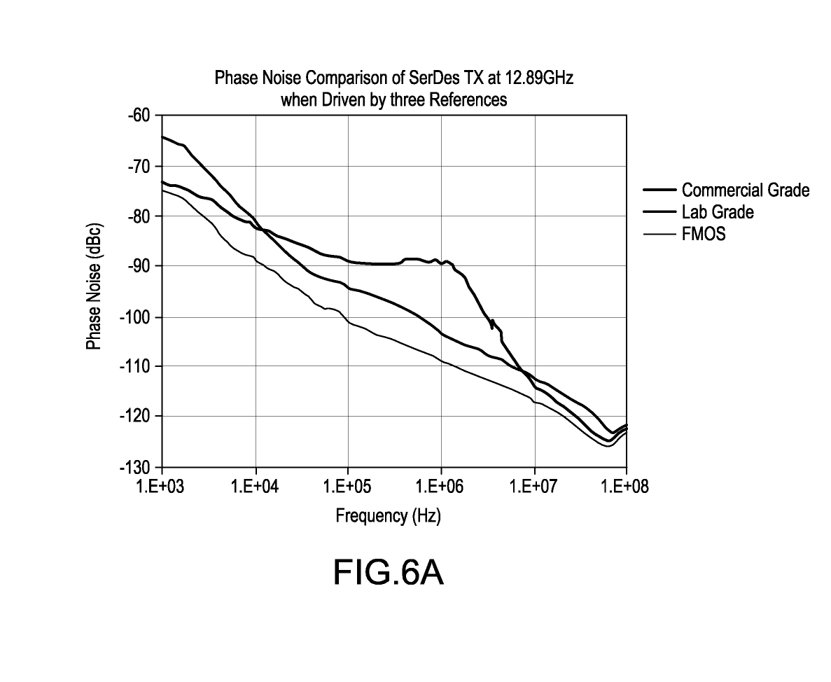

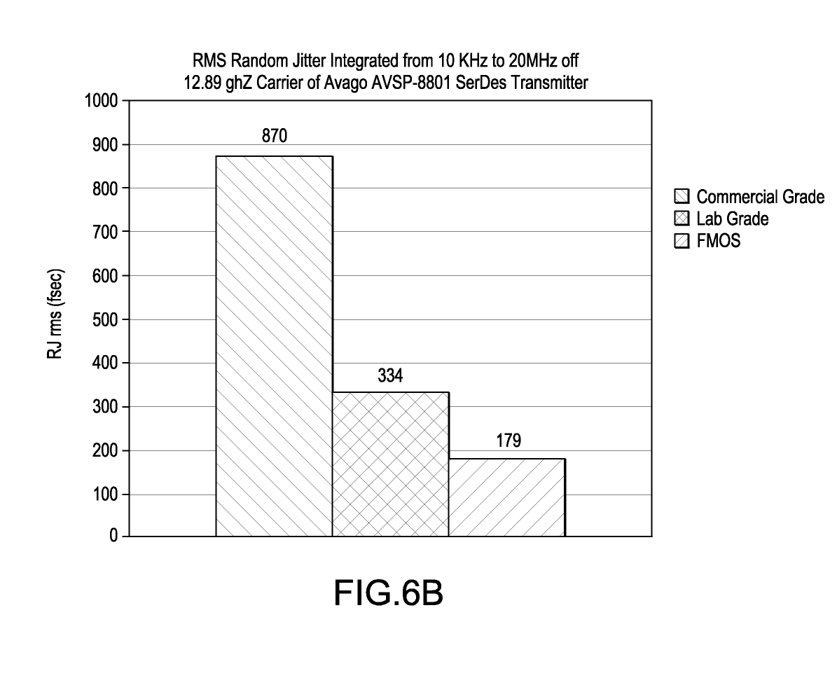

FIG. 6A is a diagram comparing phase noise of 25 Gbps SerDes clock signals, when driven by the FMOS oscillator of a representative embodiment as the reference clock oscillator and when driven by two other sources. Similar to when looking at the raw oscillator phase noise, the commercial-grade device results in the worst performance, the FMOS oscillator reference clock results in the best performance, and the lab-grade supply in the middle. Notably, the edge-repeatability of an approximately 13 GHz transmission clock signal is evaluated in connection with FIG. 6A. More broadly, it should be understood that the transmission clock signal can comprise approximately a Ku band signal. As shown in FIG. 6A, when the FBAR oscillator is used as the reference clock, the transmission clock signal can have ultra-low phase noise characteristics.

There are also positive effects provided by the chip as well, such as the TX PLL's low-pass filter, and on-die power supply bypass capacitance. In fact, shown later, the bang-bang type RX PLL in these SerDes does a lot to clean up the poorer clock sources. Still, clear differentiation, and advantage, remains with the FMOS source at this step.

A numerical comparison, provided by the RMS random jitter, is shown in FIG 6B. FIG. 6B is a diagram comparing jitter of 12.89 GHz carrier or transmission clock signal for the SerDes serializer transmission circuit (TX), when driven by the FMOS oscillator as the reference clock oscillator and when driven by two other sources.

The PLL also had adjustable bandwidth, and empirical best settings were used. Here, again, the FMOS oscillator of a representative embodiment as a reference clock is an enabling technology, because of the following “trick”: by increasing the bandwidth, the PLL can gain immunity to power supply noise. The mechanism, ironically, is that the local/self power noise is followed more strongly, but thus “tracked out” by the PLL for the transmission clock signal. This trick only works, though, when the reference clock has ultra-low phase noise at medium and far-from-carrier offsets (e.g. as in the FMOS oscillator of a representative embodiment), as the increasing bandwidth also makes the PLL track harder to the wander of the clock. In a modern receiver, the tracking PLL (if designed well) can ‘track out’ low frequency (close-in to carrier phase noise) drifts for the transmission clock signal, taking beneficial advantage of the ultra-low phase noise of the FMOS oscillator.

Unlike most commercial oscillators for communication systems, the native oscillation frequency of the FMOS oscillator of representative embodiments are, illustratively, is on the order of gigahertz (GHz). This enables applications in Gbps serial designs, without using as-large a divider-ratio as is typical, to multiply-up the reference clock to the final bitrate to be used with the transmission clock signal. If the multiplication factor is reduced, then the total jitter of the system is reduced. In this case, a PLL divider of only 40 was required for a 644.53 MHz reference clock to produce the 12.89 GHz transmission clock signal for the SerDes serializer transmission circuit (TX), compared to the classic 100GE *R4 configuration at DIV165 of a 156.25 MHz oscillator. Further improvements could be realized through the use of the native frequency of the FMOS oscillator at its 2576 MHz output; with further improvements being obtained by recovering all of the far-from-carrier phase noise of the oscillator without the PLL dividers.

As toward ever-higher bitrates are desired, enabling technologies, such as feed-forward-equalization (FFE), continuous-time-linear-equalization (CTLE), and decision-feed-back-equalization (DFE), have resulted in complex and partially-correlated total system responses (i.e. in the mathematical sense: channel pulse response). This, in combination with challenging signal integrity at microwave speeds, has led most in the industry to design closed-system prototypes, using the real board materials, connectors, and chips, intended for their final product.

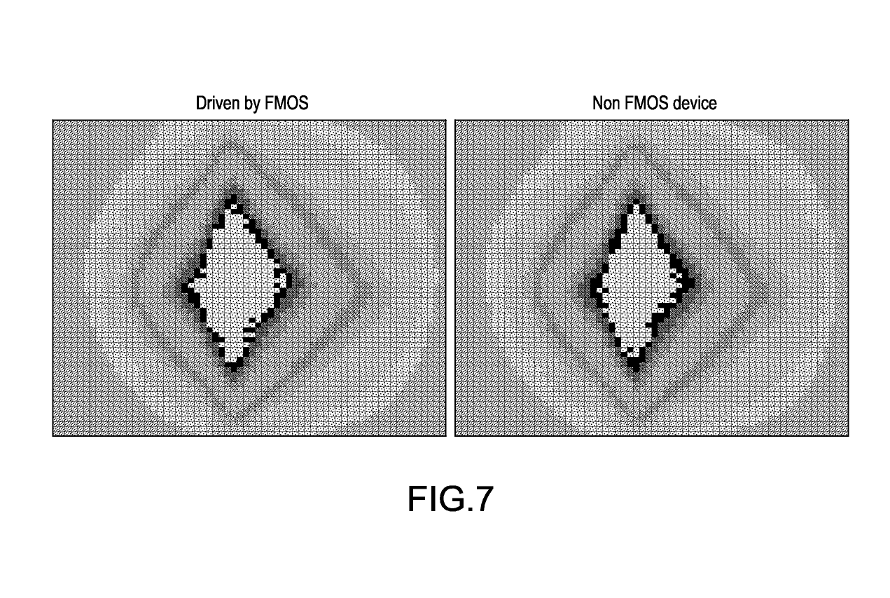

As indicated previously with reference to FIG. 4, Optical data Sink system 400 may be evaluated using gearbox integrated circuit 471. For comparison purpose, a similar data link may be obtained using a known data link system (not shown) (i.e., without any FMOS devices). The result of this comparison, is shown in FIG. 7 through eye diagrams. Accordingly, to determine if a full link budget could truly benefit from an improved reference oscillator (e.g. the FMOS oscillator reference clock of a representative embodiment) the evaluation system as depicted in the block diagram of FIG. 4 was constructed.

The SerDes gearbox integrated circuit described above was used to provide equalization and shaping to the signal. The serialized data stream signal output generated by the serializer transmission circuit (TX) of the SerDes gearbox integrated circuit described was fed into the optical portion of the link, followed by several meters of optical fiber, before feeding back to the electrical domain and then compared against itself on the SerDes chip. Eye-diagrams as shown in FIG. 7 were generated by the SerDes software.

With reference to FIG. 4, a multi-platform PCB was designed for this purpose. For the copper portion of the link, a 1-28 Gbps 2:1×5 gearbox commercially available from Avago Technologies, San Jose, Calif. (USA) (e.g. GEARBOX shown in FIG. 4) was used. The above-referenced eight-channel retimer was used as the PATTGEN in FIG. 4. For the test pattern, an industry standard pseudo-random bit-sequence of (2̂32)−1 (PRBS31) was used. This pattern is stressful due to long strings of repeated ones and zeros. All aggressors were enabled, and also sending PRBS31. In addition to eye plots shown in FIG. 7, an on-die PRBS error-checker was used to verify error-free operation of the victim. On the optical side, a 25 Gbps “GEM” embedded optic module platform was employed: independent Optics RX Module and Optics TX Module blocks, launching VCSEL arrays in to optical ribbon cables, to achieve a 300 Gbps link as shown in FIG. 4.

To reduce the scope of the experiment, only the two reference clock sources at the extremes of performance were exercised: the above-referenced known clock generator, and the FMOS oscillator reference clock of a representative embodiment, both at the same frequency of 644.5 MHz, and both DIV 40 to achieve the 25.78125 Gbps 100GE standard. The following setup is shown in FIG. 4: a PRBS31 pattern from the pattern generator (PATGENN) is (1) launched from the gearbox integrated circuit's serializer transmission circuit (TX), (2) received by the TX GEM module electrical-side, (3) transmitted optically by the GEM's Optics Module TX VCSEL array, (4) looped back optically through the Optical Channel, (5) received by the OEM's Optics RX module, and (6) finally transmitted electrically to the victim gearbox receiver, or more specifically to the deserializer receiver circuit (RX) having the clock and data recovery circuit (CDR). Accordingly, in light of the foregoing, it should be understood that the deserializer receiver circuit (RX) having the clock and data recovery circuit (CDR) shown in FIG. 4 can be coupled with the serializer transmission circuit (TX) and configured to substantially recover the transmission clock signal from the data stream signal as a recovered clock signal. The recovered clock signal can have ultra-low phase noise characteristics and the recovered clock signal can comprise approximately a Ku band signal. Further, all other parallel data channels of the pattern generator (PATTGEN) coupled with the serializer transmission circuit (TX) in the SerDes gearbox were enabled and running PRBS31 at 25 Gbps. In particular, two randomly selected channels were evaluated.

As a closed system, the performance cannot be measured externally by oscilloscope, so instead the on-die eye plotting feature of the silicon is used. This employs a test channel, whose final-stage sensing-amplifier's sampling point can be stressed by voltage and time offsets. A string of data using PRBS31 coding sequence was transmitted continuously at the input and then compared against itself at the output. Accumulated error rates are measured and plotted for various offsets in voltage and time (inside the eye diagram of FIG. 7). The dwell time for each pixel in the eye diagram measurement was 1E8 bits, that is, the number of bits sent and received for the total system. This corresponds to a Q of 5.6 (i.e. one error per 1E8 bits, will be detected by our test set up directly). Beyond this, the BER (or Q) is extrapolated. To do a reasonable comparison, extrapolated. Q's to 7, which is 4 orders lower than the measured BER, were analyzed, with particular view to determine if the data follow a linear fit.

Each eye-diagram shown in FIG. 7 is a cumulative distribution function. Estimated deterministic and random-jitter values can be calculated. This requires plotting and calculating with the Q-function (the inverse of the error function). Calculations use transition-adjusted BER, as the goal is to determine the probability of an error, only when a transition has occurred, which on average for PRBS (pseudo random, bit sequence), is every two data bits. For comparison, we studied two different closed loop channels (optical plus SerDes). Accordingly, it should be understood that FIG. 7 shows two eye diagrams for the system as described above, for one of the two channels. The equalizers on the SerDes gearbox chip were optimized to give the best signal integrity possible. The eye diagram on the left uses the FMOS oscillator and the eye diagram on the right uses the standard oscillator. As discussed in greater detail subsequently herein, even without looking at the measured statistics, there is a qualitative improvement using the FMOS oscillator reference clock of a representative embodiment.

The tests were repeated multiple times with different settings for the equalizers, different dwell times and different PRBS codes, as well as looking at various optical, channels. And, although the values for the eye width for Q=7 (10-12 BER) vary under different experimental conditions, for both horizontal and vertical BTCs, a consistent signal is obtained, revealing that the FMOS oscillator reference clock of a representative embodiment is better than a known available clock.

In other words, the estimated Bit Error Rate (BER) at eye closure, eye closure rate, and estimated deterministic and random-jitter values can be calculated. This requires plotting and calculating with the Q-function (the inverse of the error function). Calculations use transition-adjusted BER, as the goal is to determine the probability of an error, only when a transition has occurred, which, on average for PRBS (pseudo random bit sequence), is every two data bits. For comparison, two different closed loop channels (optical plus SerDes) were evaluated.

In light of the foregoing, it should be understood that FIG. 7 shows two eye diagrams for the system as described above for one of the two channels. The equalizers on the SerDes chip were optimized to give the best signal integrity possible. The eye diagram on the left uses the FMOS oscillator reference clock and the eye diagram on the right uses the standard clock. As mentioned previously herein, even without looking at the measured statistics, there is a qualitative improvement using the FMOS oscillator reference clock of a representative embodiment. First, studying the horizontal eye width statistics: to meet an extrapolated BER of approximately 10 to approximately 12 (Q of approximately 7), the effective eye-diagram width using the FMOS oscillator reference clock may be approximately 109 mUI. In contrast, for the standard clock, the effective opening may be 78 mUI (there may be an approximately 40% improvement in the horizontal random jitter).

Also, recent standards, such as CEI-25G-LR produced by the Optical Internetworking Forum, have adapted to these realities, and now consider the concept of a complete link, including the predicted random-jitter floor presented to the final sensing amplifier within the SerDes receiver. When evaluating a transmitter, raw TX phase noise is collected, and then some model must be included for the band-shaping of the receiver. In the case of random jitter, ISI effects of the channel generally did need not be considered as good board launches and cables were used here, to assure the equipment was seeing the closest thing possible to the chip's direct performance.

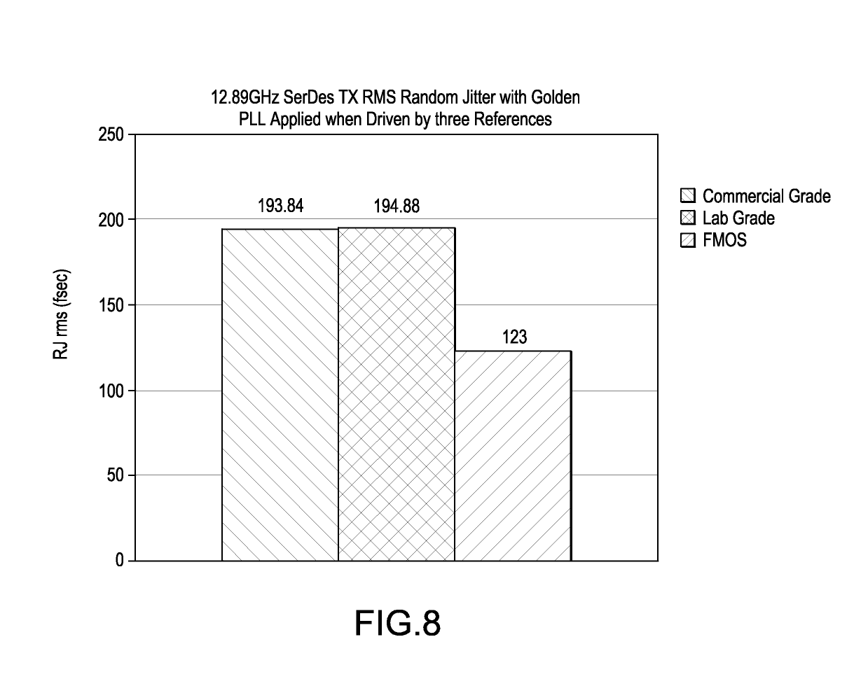

Additionally raw TX measurements can be analyzed by going through a “golden PLL model,” which in the case of the example specification, is the bitrate divided by 2578, or 10 MHz at 25 Gbps. The golden-PLL may be applied via software in the latest oscilloscopes, or here, a Matlab script was used to predict the final values. FIG. 8 compares the numerical results.

FIG. 8 is a diagram comparing calculated jitter at the final receiver stage of a 25 Gbps link, when driven by the FMOS oscillator of a representative embodiment as the reference clock oscillator and when driven by two other sources. These results given in FIG. 8 show the effect of a closed system with FFE, CTLE, DFE, and PLL shaping applied. There are two conclusions; i) with the turning on the various equalizers, there is no difference in net jitter between the lab-grade oscillator with jitter approximately 2.5 times better jitter than a known oscillator. Secondly, the effect of random, jitter on the noise floor of the system emerges: A clear performance advantage of the ultra-low jitter FMOS device of a representative embodiment (there may be almost 40% improvement), which bolsters the assertion that a real link jitter budget can be relieved by improved reference clocks. A simple-minded inference is that with the FMOS oscillator reference clock of a representative embodiment either the BER can be improved at the existing clock speeds, or one can use less expensive connectors or boards to meet cost targets.

Furthermore, there is hope that well-designed equalizers will ultimately minimize deterministic jitter, leaving only the random jitter to be dealt with. Using the FMOS oscillator reference clock as the ‘Gold Standard’ oscillator can help with design iterations to guide designers towards better equalizers.

Beneficially, better results were found with the FMOS device of representative embodiments, from the perspective of the individual oscillators' raw output, through the link budget of an end-to-end complex system. This was not always a foregone conclusion, until measurements of real chips were performed. Exploration of non-standard PLL gain settings, lower total reference-to-bitrate ratios, and turning off optical CDR blocks, were all enabled by the operating range opened up by the FBAR technology.

Comparison was made between the FMOS device (and carrier board) of representative embodiments and various known oscillators clock generators. Notably the FMOS oscillator is a fixed frequency source. Re-targeting frequencies can be done, e.g., by only processing a new acoustic stack thickness.

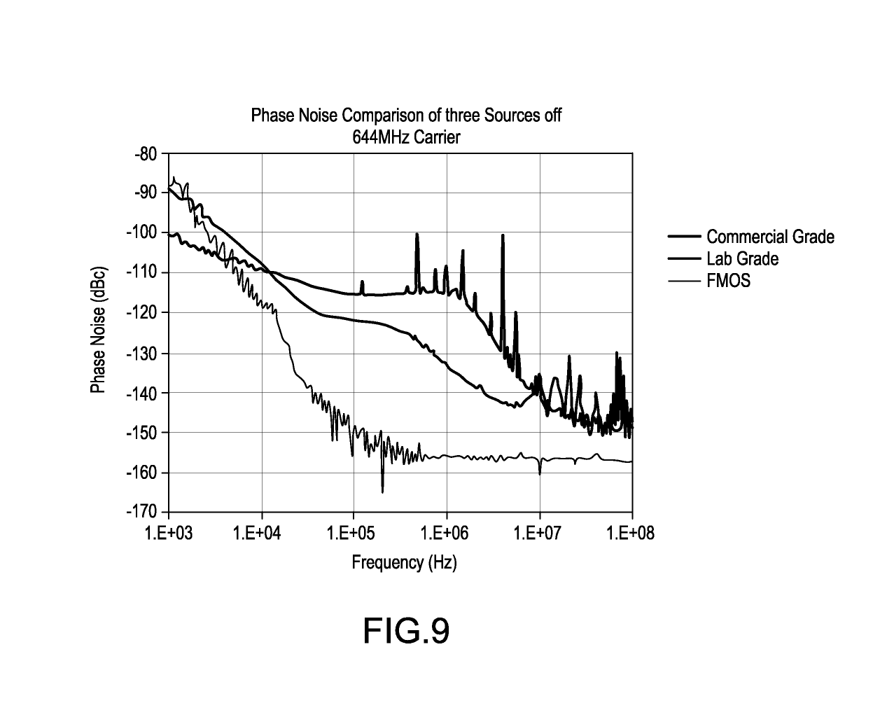

For the fairest assessment possible, all devices were programmed to the same carrier frequency, and measured at the same time, under the same conditions. The phase noise plots are shown in FIG. 9. Accordingly, FIG. 9 is a diagram comparing phase noise of the FMOS oscillator to two other sources.

In all cases shown in FIG. 9, a resonator is not evaluated when the term oscillator is used. Rather, a source resonator paired with some combination of dividers/PLLs, and a final driver stage.

As expected, the commercial-grade clock-source has the highest phase noise of the three, but certainly not an unreasonable value. It starts with good close-in phase noise, and then levels off in the mid-band, where PLL performance typically dominates. The lab-grade oscillator starts higher, but then nicely plunges, continually through the mid-band, and in to the far-from-carrier region.

Finally, the FMOS device of a representative embodiment shows by comparison, markedly improved phase noise performance, especially considering some of the spikes are pick-up noise from the ambient. The close-in phase noise does rather start high, but rapidly plunges near the floor of the instrument, and stays there.

It is useful to note that in a modern SerDes application, the close-in phase noise of the transmitter (from any of the oscillators), is not a significant issue, because a PLL-based receiver on the other end can track out low-frequency drift. Admittedly, there are applications where the close-in phase noise is important, and this may well become an area of active development for a final product.

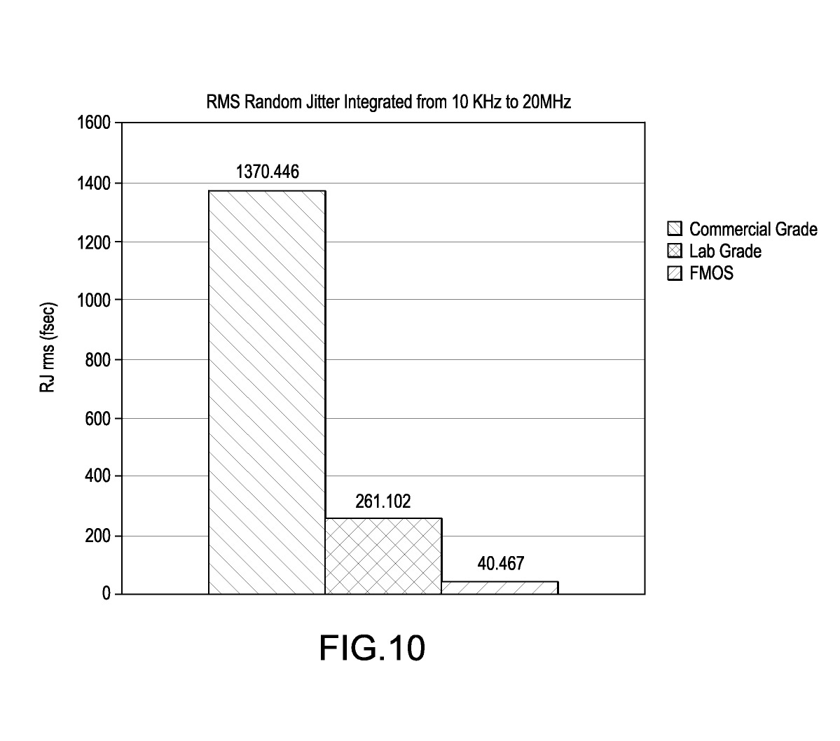

The far-from-carrier performance is exactly what the FMOS technology enables. Further, as discussed previously herein, the temperature stability is quite consistent (from −40 C to +125 C), and the manufacturability is high. A numerical comparison of RMS random jitter is shown in FIG. 10. Accordingly, FIG. 10 shows a diagram comparing jitter of the FMOS oscillator to two other sources.

As can be appreciated, the various FMOS-based devices described herein provide comparatively ultra-low jitter reference clocks, with performance improvements at each stage of assembling a full example system. Illustratively, a low jitter clock is provided from tire up-conversion of the native frequency to a 13 GHz frequency, through the SerDes transmitter, the electrical to optical module and back.

While example embodiments are disclosed herein, one of ordinary skill in the art appreciates that many variations that are in accordance with the present teachings are possible. The invention therefore is not to be restricted except within the scope of the claims

What is claimed is:

1. A communication apparatus comprising:
an ultra-low phase noise reference oscillator configured to generate an ultra-high frequency reference clock signal;
a phase locked loop circuit (PLL) coupled with the ultra-low phase noise reference oscillator and configured to generate a transmission clock signal based on the ultra-high frequency reference clock signal; and
a serializer transmission circuit (TX) coupled with the ultra-low phase noise reference oscillator through the phase locked loop circuit (PLL), the serializer transmission circuit (TX) configured to receive the transmission clock signal and a plurality of data channels in parallel and wherein the serializer transmission circuit (TX) transmits data serially as a data stream signal.

2. A communication apparatus as recited in claim 1, wherein the ultra-low phase noise reference oscillator has ultra-low phase noise characteristics comprising at least one of: between approximately −120 dBC/Hz and approximately −110 dBC/Hz at 10 kHz offset from carrier of the ultra-high frequency reference clock signal, between approximately −140 dBC/Hz and approximately −130 dBC/Hz at 100 kHz offset from earner of the ultra-high frequency reference clock signal, and between approximately −160 dBC/Hz and approximately −150 dBC/Hz at 1 MHz offset from carrier of the ultra-high frequency reference clock signal.

3. A communication apparatus as recited in claim 1, wherein the ultra-low phase noise reference oscillator has ultra-low phase noise characteristics comprising integrated jitter of approximately twenty femtoseconds or less.

4. A communication apparatus as recited in claim 1 wherein the ultra-high frequency reference clock signal comprises approximately an S band signal.

5. A communication apparatus as recited in claim 1, wherein the phase locked loop circuit (PLL) coupled with the ultra-low phase noise reference oscillator is configured so that the transmission clock signal has ultra-low phase noise characteristics.

6. A communication apparatus as recited in claim 5, wherein the ultra-low phase noise characteristics of the transmission clock signal comprise at least one of: between approximately −90 dBC/Hz and approximately −100 dBC/Hz at 10 kHz offset from carrier of the ultra-high frequency reference clock signal between approximately −110 dBC/Hz and approximately −100 dBC/Hz at 100 kHz offset from carrier of the ultra-high frequency reference clock signal, and between approximately −110 dBC/Hz and approximately −100 dBC/Hz at 1 MHz offset from carrier of the ultra-high frequency reference clock signal.

7. A communication apparatus as recited in claim 5, wherein the ultra-low phase noise characteristics of the transmission clock signal have integrated jitter of approximately two-hundred femtoseconds or less.

8. A communication apparatus as recited in claim 1, wherein the transmission clock signal comprises approximately a Ku band signal.

9. A communication apparatus as recited in claim 1, wherein the phase locked loop circuit (PLL) coupled with the ultra-low phase noise reference oscillator is configured to substantially reduce close-in phase noise for the transmission clock signal by substantially tracking-out close-in phase noise of the ultra-low phase noise reference oscillator.

10. A communication apparatus as recited in claim 1, wherein the serializer transmission circuit (TX) coupled with the ultra-low phase noise reference oscillator through the phase locked loop circuit (PLL) is configured to transmit data serially as part of a 100 gigabit ethernet system.

11. A communication apparatus as recited in claim 1, wherein the serializer transmission circuit (TX) coupled with the ultra-low phase noise reference oscillator through the phase locked loop circuit (PLL) is configured to transmit data serially as part of a 300 gigabit per second optical data link.

12. A communication apparatus as recited in claim 1, further comprising a deserializer receiver circuit (RX) having a clock and data recovery circuit (CDR) coupled with the serializer transmission circuit (TX) and configured to substantially recover the transmission clock signal from the data stream signal as a recovered clock signal.

13. A communication apparatus as recited in claim 12, wherein the recovered clock signal has ultra-low phase noise characteristics.

14. A communication apparatus as recited in claim 12, wherein the recovered clock signal comprises approximately a Ku band signal.

15. A communication apparatus as recited in claim 1, wherein the ultra-low phase noise reference oscillator comprises:
a base substrate comprising a bonding pad provided thereover;
a bulk acoustic wave (BAW) resonator disposed on the base substrate;
a lid substrate comprising a bonding pad seal provided thereover, the bonding pad seal bonding with the bonding pad to define a hermetically sealed volume between the lid substrate and the base substrate;
a material layer region provided over a portion of a first surface of the lid substrate within the hermetically sealed volume; and
electronic circuitry provided over or in the material layer region.

16. A communication apparatus as recited in claim 1, wherein the ultra-low phase noise reference oscillator comprises a temperature compensated BAW resonator.

17. A communication apparatus as recited in claim 1 wherein the BAW resonator comprises a film bulk acoustic resonator (FBAR) or a solidly mounted resonator (SMR).

18. A communication apparatus as recited in claim 1 wherein the ultra-low phase noise reference oscillator comprises a zero drift resonator.

19. A communication apparatus comprising:
a serializes transmission circuit (TX) configured to receive a plurality of data channels in parallel and wherein the serializer transmission circuit (TX) transmits data serially as a data stream signal; and
a film bulk acoustic resonator (FBAR) or a solidly mounted resonator (SMR) coupled with the serializer transmission circuit (TX).

20. A communication apparatus as recited in in claim 19 wherein the film bulk acoustic resonator or solidly mounted resonator is part of an ultra-low phase noise reference oscillator configured to generate an ultra-high frequency reference clock signal.

21. A communication apparatus comprising:
a base substrate having a bonding pad provided thereon;
an bulk acoustic wave (BAW) resonator disposed on the base substrate;
a lid substrate having a bonding pad seal provided thereon, the bonding pad seal bonding with the bonding pad to define a hermetically sealed volume between the lid substrate and the base substrate;
a serializer transmission circuit (TX) coupled with the acoustic resonator and configured to receive a plurality of data channels in parallel and wherein the serializer transmission circuit (TX) transmits data serially as a data stream signal.

22. A communication apparatus as recited in in claim 21 wherein the BAW resonator is part of an ultra-low phase noise reference oscillator configured to generate an ultra-high frequency reference clock signal.
